(19) United States
(12) Patent Application Publication
(10) Pub. No.: US 2003/0098720 A1
(43) Pub. Date: May 29, 2003

(54) Lock detect indicator for a phase locked loop

(76) Inventors: Pradeep Trivedi, Sunnyvale, CA (US); Gin Yee, Sunnyvale, CA (US)

Correspondence Address: Rosenthal & Osha, L.L.P., Suite 4550, 700 Louisiana, Houston, TX, 77002, US

(21) Appl. No.: 09/997,472

(22) Filed: Nov. 29, 2001

(51) Int. Cl. H03D 13/00

(52) U.S. Cl. 327/12

(57) ABSTRACT

A lock detect indicator capable of dynamically determining whether a phase locked loop is in lock or out of lock is provided. The lock detect indicator uses pulses on the fast and slow signals generated by a phase-frequency detector of the phase locked loop to determine if the phase locked loop has been continuously trying to speed up or slow down itself for a predefined amount of time, in which case, the lock detect indicator indicates that the phase locked loop is out of lock. Further, a lock detect indicator capable of indicating whether a phase locked loop previously went out of lock is provided. Further, a method for detecting whether a phase locked loop is out of lock or in lock is provided.

### BACKGROUND OF INVENTION

As shown in FIG. 1, a typical computer system (10) has, among other components, a microprocessor (12), one or more forms of memory (14), integrated circuits (16) having specific functionalities, and peripheral computer resources (not shown), e.g., monitor, keyboard, software programs, etc. These components communicate with one another via communication paths (19), e.g., wires, buses, etc., to accomplish the various tasks of the computer system (10).

In order to properly accomplish such tasks, the computer system (10) relies on the basis of time to coordinate its various operations. To that end, a crystal oscillator (18) generates a system clock signal (referred to and known in the art as “reference clock” and shown in FIG. 1 as sys_clk) to various parts of the computer system (10). However, modem microprocessors and other integrated circuits are typically capable of operating at frequencies significantly higher than the signals most clock oscillators can provide, and thus, it becomes important to ensure that operations involving the microprocessor (12) and the other components of the computer system (10) use a proper and accurate reference of time.

One component used within the computer system (10) to ensure a proper reference of time among a system clock and a microprocessor clock, i.e., “chip clock,” is a type of clock generator known as a phase locked loop, or “PLL” (20). The PLL (20) is an electronic circuit that controls an oscillator such that the oscillator maintains a constant phase relative to a system signal. Referring to FIG. 1, the PLL (20) inputs the system clock as its reference signal and outputs a chip clock signal (shown in FIG. 1 as chip_clk) to the microprocessor (12), where the system clock and chip clock have a specific phase and frequency relationship controlled by the PLL (20). This relationship between the phases and frequencies of the system clock and chip clock ensures that the various components within the microprocessor (12) use a controlled and accounted for reference of time. However, when this relationship is not maintained by the PLL (20), i.e., when the PLL (20) is “out of lock,” the operations within the computer system (10) become indeterministic.

FIG. 2 shows a typical PLL (30). The PLL (30) has a phase-frequency detector (32), a charge pump/filter (34), and a voltage controlled oscillator (36). The phase-frequency detector (32) inputs a reference clock signal (shown in FIG. 2 as sys_clk), typically a system clock of a computer system, and a chip clock (shown in FIG. 4 as chip_clk) signal fed back from an output of the PLL (30) (discussed below). The phase-frequency detector (32) detects a difference between a phase of the system clock and the chip clock. If a phase of the chip clock lags behind a corresponding phase of the system clock, the phase-frequency detector (32) indicates to the rest of the PLL (30) that the chip clock needs to be sped up. This indication is given by generating an elongated pulse to the charge pump/filter (34) via a fast signal (shown in FIG. 2 as fast_pulse). Alternatively, if a phase of the system clock lags behind a corresponding phase of the chip clock, the phase-frequency detector (32) indicates to the rest of the PLL (30) that the chip clock needs to be slowed down. This indication is given by generating an elongated pulse to the charge pump\filter (34) via a slow signal (shown in FIG. 2 as slow_pulse). Those skilled in the art will note that when the PLL (30) is in lock, there are still pulses on the fast and slow signals. However, in this case, i.e., when the PLL is in lock, the fast and slow signal pulses are equal and relatively short.

The charge pump/filter (34), depending on the fast and slow signals from the phase-frequency detector (32), either dumps or removes charge to/from a voltage signal which is used by the voltage controlled oscillator (36) to generate the chip clock. The chip clock is then fed back to the input of the phase-frequency detector (32) for continued maintenance.

In effect, the PLL (30) generates the chip clock such that it has a specific relationship with the system clock When this relationship is maintained, i.e., when the PLL is “in lock,” the timing of operations within a computer system occur as expected, and performance goals can be achieved. However, when the PLL is “out of lock,” operations occur unexpectedly causing computer system performance degradation. Further, if the PLL happens to be out of lock at the time that blocks on an integrated circuits are powered up, then there is a propensity for the output of the VCO of the PLL to go to a very high frequency, which, in turn, may cause severe damage to the integrated circuit. Thus, not only is it critical that the PLL stays in lock during integrated circuit operation, but it is also critical that the PLL be in lock at the time the integrated circuit is powered up. Moreover, it is important to know when and if the PLL goes out of lock so that remedial action may be taken.

### SUMMARY OF INVENTION

According to one aspect of the present invention, a computer system comprises a phase locked loop having a phase-frequency detector, where the phase-frequency detector inputs a system clock and generates a chip clock, and where the phase-frequency detector generates pulses on a first signal and second signal dependent on a relationship between the system clock and the chip clock; and a lock detect indicator that uses the first and second signals to determine whether the phase locked loop is out of lock.

According to another aspect, an integrated circuit comprises circuitry that generates a first lock signal dependent on a first signal and a second signal used in a clock generator, circuitry that generates a lock reset signal dependent on the first lock signal and a reset input signal, circuitry that generates a second lock signal dependent on the lock reset signal, and circuitry that outputs a lock status signal dependent on the second lock signal.

According to another aspect, an integrated circuit comprises generating means for generating a chip clock signal based on a system clock signal, where the generating means uses a first signal and a second signal to maintain a relationship between the chip clock and the system clock; detecting means for using the first and second signals to determine whether the generating means is out of lock; and indicating means for indicating whether the generating means is out of lock.

According to another aspect, a method for detecting whether a phase locked loop is out of lock comprises determining whether a pulse of a first signal or a second signal used in the phase locked loop is greater than a predetermined width, generating a pulse on a first lock signal based on the determination, and dynamically generating a pulse on a lock status signal dependent on the pulse on the first lock signal.

Other aspects and advantages of the invention will be apparent from the following description and the appended claims.

### BRIEF DESCRIPTION OF DRAWINGS

FIG. 1 shows a typical computer system.

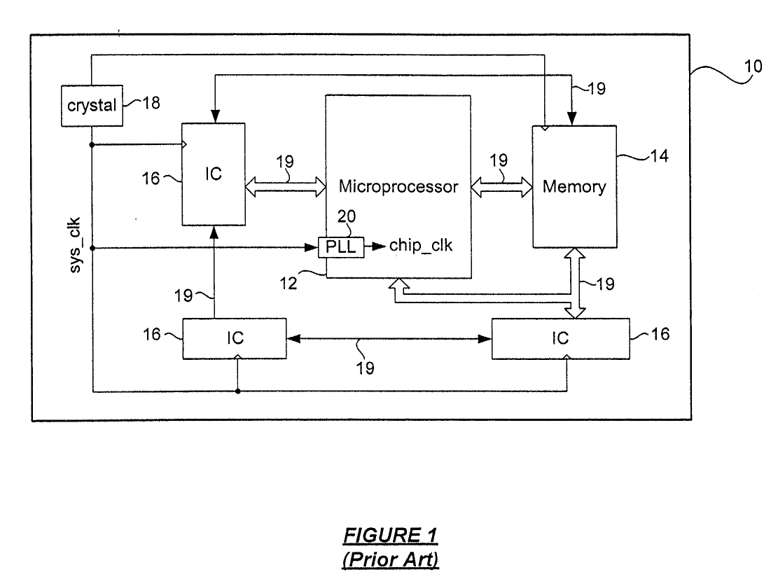

FIG. 2 shows a typical PLL.

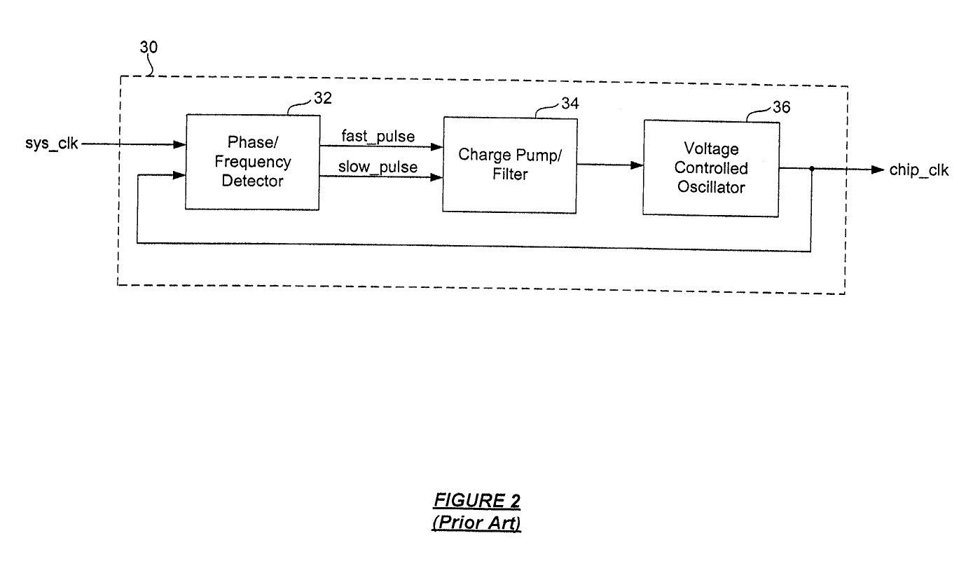

FIG. 3 shows a block diagram in accordance with an embodiment of the present invention.

FIG. 4 shows a circuit in accordance with an embodiment of the present invention.

### DETAILED DESCRIPTION

Embodiments of the present invention relate to an apparatus for determining whether a phase locked loop (“PLL”) is locked. Embodiments of the present invention further relate to an apparatus for determining whether a PLL has ever lost lock. Embodiments of the present invention further relate to a method for determining whether a PLL is locked. Embodiments of the present invention further relate to a method for determining whether a PLL has ever lost lock. Embodiments of the present invention also relate to a computer system having a PLL lock detect indicator component. Embodiments of the present invention further relate to a method for ensuring computer system performance by determining when and if a PLL within the computer system is or has been out of lock. Embodiments of the present invention further relate to a method and apparatus for testing and debugging a phase locked loop.

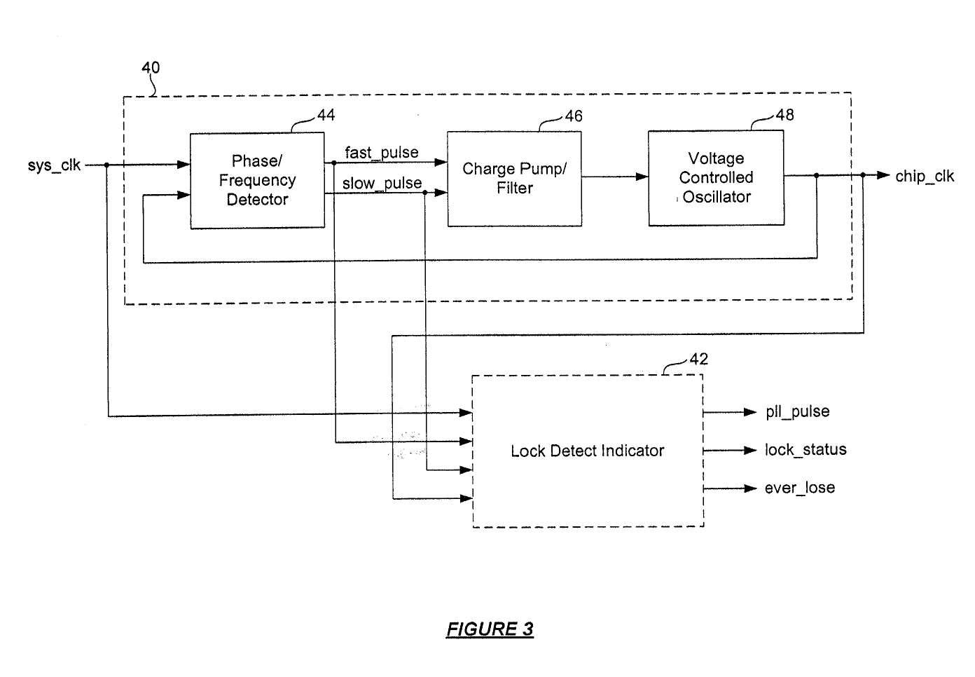

FIG. 3 shows an exemplary block diagram in accordance with an embodiment of the present invention. Specifically, FIG. 3 shows a PLL (40) and a lock detect indicator (42). The PLL (40) has a phase-frequency detector (44), a charge pump/filter (46), and a voltage controlled oscillator (48). The phase-frequency detector (44) inputs a system clock (shown in FIG. 3 as sys_clk) and a chip clock (shown in FIG. 3 as chip_clk) that is fed back from an output of the voltage controlled oscillator (48). The phase-frequency detector (44), depending on whether a phase of the chip clock is lagging or leading a corresponding phase of the system clock, generates an elongated pulse to the charge pump/filter (46) on either a fast signal (shown in FIG. 3 as fast_pulse) or a slow signal (shown in FIG. 3 as slow_pulse).

Then, depending on the output from the phase-frequency detector (44), the charge pump/filter (46) dumps or removes charge to/from a voltage signal to the voltage controlled oscillator (48). Depending on that signal, the voltage controlled oscillator (48) generates the chip clock. The chip clock serves as an output of the PLL (40) as well as a feedback signal to the phase-frequency detector (44).

The lock detect indicator (42), in addition to inputting the system clock and the chip clock, inputs the fast and slow signals from the phase-frequency detector (44). By using the fast and slow signals to determine whether the phase-frequency detector (44) has been trying to continuously speed up or slow down the PLL (40) for too long a period of time, the lock detect indicator outputs a lock status signal (shown in FIG. 3 as lock_status), a PLL pulse signal (shown in FIG. 3 as pll_pulse), and a past lock signal (shown in FIG. 3 as ever_lose). The lock status signal indicates whether the PLL is “in lock” or “out of lock.” The PLL pulse signal is used as another indicator of whether the PLL is in lock or out of lock. The past lock signal indicates whether the PLL (40) has lost lock during a previous predetermined amount of time.

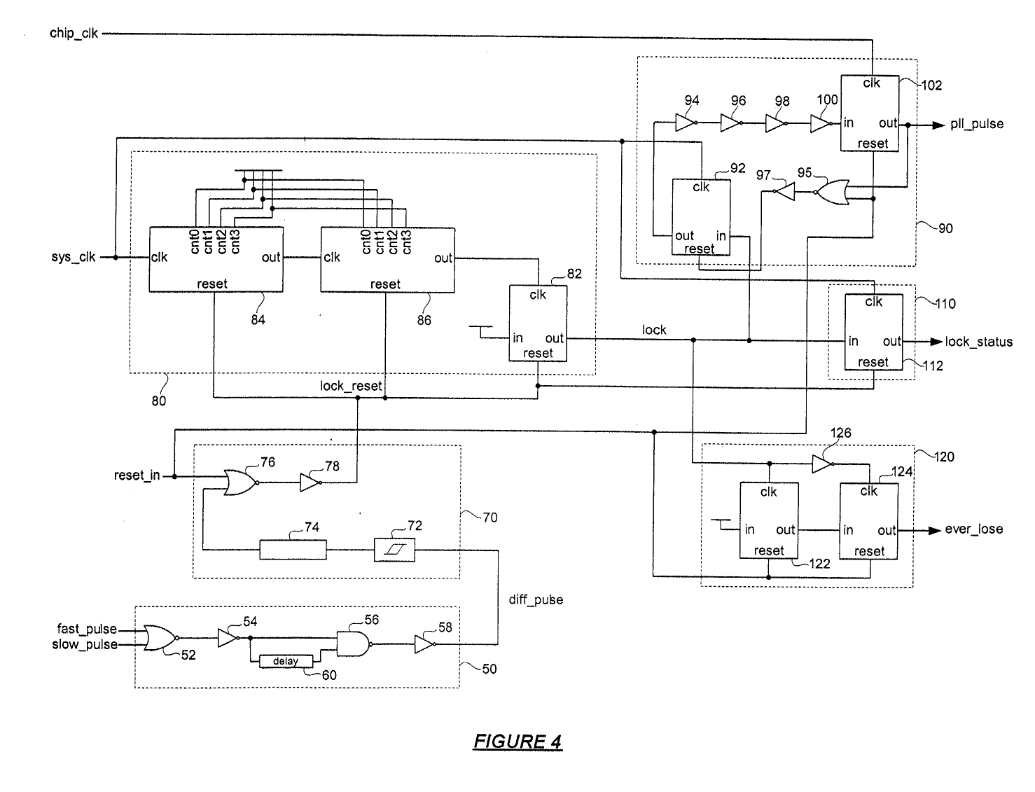

FIG. 4 shows an exemplary circuit of the lock detect indicator (42) in accordance with the embodiment shown in FIG. 3. The fast signal and the slow signal from the phase-frequency detector (44) serve as inputs to a first stage (50) of the lock detector indicator (42).

In the first stage (50), a NOR gate (52) inputs the fast and slow signals from the PLL (40). Recall that if the PLL (40) is in lock, the pulses on the fast and slow signals are equal and relatively short. Thus, when the PLL (40) is in lock, if both the fast and slow signals are low, the NOR gate (52) outputs high to a first inverter (54), which, in turn, outputs low to a first input to a NAND gate (56). Thereafter, the NAND gate (56) outputs high to a second inverter (58), which, in turn, outputs low on a pulse difference signal (shown in FIG. 4 as diff_pulse). A low value on the pulse difference signal essentially indicates that the PLL (40) is in lock.

Alternatively, when the PLL (40) is in lock, if both the fast and slow signals pulse high for a relatively short amount of time, an OR function (formed by the NOR gate (52) and the first inverter (54)) essentially selects the wider of the pulses on the fast and slow signals, and accordingly outputs high to the first input of the NAND gate (56). A delay element (60), which inputs the signal from the first inverter (54) and outputs to a second input of the NAND gate (56), has a delay greater than the minimum width of a pulse on either the fast or slow signal, where the minimum pulse width is representative of fast and slow signal pulses when the PLL (40) is in lock. Thus, when the PLL (40) is in lock, and the first inverter (54) outputs high to both the first input of the NAND gate (56) and the delay element (60), the NAND gate (56) outputs high because the delay introduced by the delay element (60) is greater than the pulse width from the first inverter (54), i.e., the first input of the NAND gate (56) is high and the second input of the NAND gate (56) is low. Thus, in turn, the second inverter (58) outputs low to the pulse difference signal.

However, in the case that the PLL (40) goes out of lock, either the fast or slows signal pulses high for a period of time longer than the minimum pulse width, i.e., longer than the delay provided by the delay element (60), the NAND gate (56) outputs high for a period of time equal to the width of the fast or slow signal pulse less the minimum pulse width. Note that due to the configuration of the NAND gate (56) and the second inverter (58), the pulse difference signal is essentially an AND function of the signal from the first inverter (54) and the signal from the delay element (60). Thus, the pulse difference signal goes high when a width of a pulse on the signal generated by the first inverter (54) is greater than a width of the corresponding pulse on the signal generated by the delay element (60). It follows that when the PLL (40) goes out of lock, the pulse difference signal goes high.

Those skilled in the art will appreciate that the configuration of the first stage (50) of the lock detect indicator (42) compensates for delay inherent in the PLL (40). The delay element (60) accounts for delays caused by jitter on a clock tree of an integrated circuit and by the system clock itself. Typically, in the prior art, when there is jitter, a phase-frequency detector of a PLL may behave as if the PLL is out of lock, and thus, the phase-frequency detector may try to unnecessarily speed up or slow down particular signals in the PLL. In effect, the delay in the output of the phase-frequency detector will be longer than what it really should have been.

In the present invention, this delay is accounted for in that the lock detect indicator (42) is capable of indicating that the PLL (40) is in lock even though the PLL (40) possesses some jitter. Specifically, the pulse width output by the first inverter (54) when either of the fast or slow signals is high is compared to the delay element (60) that has a delay substantially equal to a minimum width of the fast and slow signals in the presence of regular PLL jitter. If the pulse width generated by the first inverter (54) is greater than this minimum width, the PLL (40) is determined to be out of lock.

The pulse difference signal generated in the first stage (50) serves as an input to a second stage (70) of the lock detect indicator (42). In the second stage, a Schmitt trigger (72) inputs the pulse difference signal, attenuates noise present on the pulse difference signal, and outputs a clean pulse difference signal. The Schmitt trigger (72) outputs high if its input, the pulse difference signal, remains high for some time. This ensures that glitches on the pulse difference signal do not result in a high signal from the Schmitt trigger (72). Those skilled in the art will appreciate that by removing such glitches, the pulse difference signal does not appear as if the PLL (40) is out of lock at a point in time when the PLL (40) is actually in lock.

The clean pulse difference signal generated by the Schmitt trigger (72) serves as an input to a pulse amplifier (74), which, amplifies, i.e., widens, the pulses on the clean pulse difference signal. This is necessary because, in some cases, pulses on the clean pulse difference signal may not be wide enough to activate a reset port of other components used elsewhere in the lock detect indicator (42). Thus, the pulse amplifier (74) amplifies the pulses on the clean pulse difference signal to widths recognizable by other components within the lock detect indicator (42) and generates an amplified pulse signal. The amplified pulse signal serves as a first input to a NOR gate (76). A reset input signal (shown in FIG. 4 as reset_in) to the lock detect indicator (42) serves as a second input to the NOR gate (76). If the reset input signal goes high, the NOR gate (76) outputs low to an inverter (78), which, in turn, outputs high on a lock reset signal (shown in FIG. 4 as lock_reset). However, if the reset input signal is low, the amplified pulse signal gets inverted by the NOR gate (76), and subsequently, the amplified pulse signal gets inverted again as it passes through the inverter (78).

The lock reset signal from the inverter (78) serves as an input to a third stage (80), where the third stage has a flip-flop (82) and two 4-bit counters (84, 86). Each 4-bit counter (84, 86) has a 4-bit input (shown in FIG. 4 as cnt0, cnt1, cnt2, cnt3), a clock input, a reset input, and an output port for outputting a value of the counter. The first and second 4-bit counters (84, 86) share the 4-bit inputs as shown in FIG. 4.

The system clock input (shown in FIG. 4 as sys_clk) to the lock detect indicator (42) serves as the clock input to the first 4-bit counter (84). A count signal at the output port of the first 4-bit counter (84) serves as the clock input to the second 4-bit counter (86). Thus, the first and second 4-bit counters (84, 86) effectively form an 8-bit counter (also referred to as “counter”) that is capable of incrementingly counting to 2⁸, or 256. The counter increments one for every completed cycle on the system clock.

The lock reset signal (discussed above) serves as the reset input to the first and second 4-bit counters (84, 86). If the lock reset signal does not toggle high before the counter counts 256 cycles on the system clock, then at the end of the 256^{th} system clock cycle, the counter triggers the flip-flop (82) to output a high pulse on a lock signal (shown in FIG. 4 as lock). However, if the lock reset signal does toggle high before the counter reaches 256, the counter is reset and the lock signal remains low until the next time the counter is able to reach 256.

The configuration of the counter as shown in FIG. 4 helps the lock indicator (42) operate accurately by ensuring that the lock detect indicator (42) does not indicate that the PLL (40) is in lock unless it has been in lock for at least 256 system clock cycles.

Those skilled in the art will appreciate that although FIG. 4 shows a particular counter configuration, other embodiments may use other counter configurations capable of counting a different number of values.

The lock signal generated by the flip-flop (82) serves as an input to a fourth stage (90). The fourth stage (90) generates the PLL pulse output of the lock detect indicator (42). In the fourth stage (90), the lock signal serves as an input to a first flip-flop (92) that is clocked by the system clock. The first flip-flop (92), in turn, outputs to a series of inverters (94, 96, 98, 100). The fourth inverter (100) then outputs to an input of a second flip-flop (102) that is clocked by the chip clock (shown in FIG. 4 as chip_clk) to the lock detect indicator (42). Based on the aforementioned configuration of the fourth stage (90), the second flip-flop (102) generates a pulse on the PLL pulse signal at every rising edge of the system clock, where the pulse has a width equal to one cycle of the chip clock. Further, a NOR gate (95) and an inverter (97) are placed in series in order to reset the first flip-flop (92) if the reset input signal is asserted or if there is a high transition on the PLL pulse signal.

Those skilled in the art will appreciate that the presence of the PLL pulse signal gives a designer another type of signal that indicates the lock status of the PLL.

The lock signal generated by the flip-flop (82) also serves as an input to a fifth stage (110). The fifth stage (110) generates the lock status signal output of the lock detect indicator (42). In the fifth stage (110), the lock signal serves as an input to a flip-flop (112). When the lock signal pulses high, the flip-flop (112) subsequently outputs high on the lock status signal to indicate that the PLL (40) is in lock. Conversely, if the PLL (40) goes out of lock, the lock reset signal, which is connected to a reset input of the flip-flop (112), goes high, which, in turn, resets the flip-flop (112) and causes the lock status signal to go low. Thus, when the PLL (40) is in lock, the lock status signal is high due to the lock signal, and when the PLL (40) is out of lock, the lock status signal goes low due to the lock reset signal.

The lock signal generated by the flip-flop (82) also serves as an input to a sixth stage (120). The sixth stage (120) generates the past lock signal output of the lock detect indicator (42). In the sixth stage (120), the lock signal serves as a clock input to a first flip-flop (122) that, when triggered by a rising edge of the lock signal, outputs high to an input of a second flip-flop (124). The second flip-flop (124) is clocked by an inverter (126) to which the lock signal serves as an input. Thus, the second flip-flop (124), when triggered by the falling edge of the lock signal, outputs high to indicate that the PLL (40) has, either in the past or presently, been out of lock.

Those skilled in the art will appreciate that because the lock detect indicator (42) is capable of indicating if the PLL (40) has gone out of lock in the past, a designer assessing the performance of a particular PLL does not have to focus on a dynamic lock status signal that may quickly toggle between and low, and instead, the designer may use a past lock signal that remains at a constant value after a certain event has occurred regardless of whether that event is still occurring.

Advantages of the present invention may include one or more of the following. In some embodiments, because a lock detect indicator may be used to determine whether a PLL goes out of lock, PLL performance may be assessed and improved, effectively leading to improvement in overall system performance.

In some embodiments, one may use a PLL lock detect indicator to determine whether a PLL is out of lock or in lock before a power up sequence of an integrated circuit. This is beneficial because, typically, if a PLL is out of lock at the time of power up, the PLL may generate a very high clock signal, which, in turn, may cause severe damage to the integrated circuit. Thus, in some embodiments of the present invention, because the PLL lock detect indicator can be used to determine the status of the PLL before power up, such adverse effects may be avoided.

In some embodiments, because a lock detect indicator can indicate whether a PLL has gone out of lock during a pervious predetermined amount of time, a designer may assess the PLL's performance after a particular operation instead of during the operation.

In some embodiments, because a lock detect indicator has jitter compensation circuitry, jitter normally present within a PLL does not affect the accuracy of the lock detect indicator's indications of whether the PLL is in lock or out of lock.

In some embodiments, because a lock detect indicator has counting circuitry, lock status indications from the lock detect indicator may be assured to be accurate even in the presence of chip clock jitter and system clock jitter.

In some embodiments, because a lock detect indicator provides a designer with a means by which to comprehensively assess the behavior of a phase locked loop, the lock detect indicator may be used to test and/or debug all or components of the phase locked loop.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A computer system, comprising:
a phase locked loop having a phase-frequency detector, wherein the phase-frequency detector inputs a system clock and generates a chip clock, and wherein the phase-frequency detector generates pulses on a first signal and second signal dependent on a relationship between the system clock and the chip clock; and
a lock detect indicator that uses the first and second signals to determine whether the phase locked loop is out of lock.

2. The computer system of claim 1, wherein the system clock is a system clock.

3. The computer system of claim 1, wherein the lock detect indicator comprises:
circuitry that generates a first lock indication pulse if a pulse on the first signal or second signal is longer than a predetermined pulse width;
circuitry that generates a second lock indication pulse dependent on the first lock indication pulse and a count value; and
circuitry that uses the second lock indication pulse to dynamically generate a lock status signal, wherein the lock status signal is indicative of whether the phase locked loop is out of lock.

4. The computer system of claim 1, wherein the lock detect indicator comprises:
circuitry that outputs another lock status signal, wherein the another lock status signal is indicative of whether the phase locked loop is out of lock.

5. The computer system of claim 1, wherein the lock detect indicator comprises:
circuitry that outputs a past lock status signal, wherein the past lock status signal indicates whether the phase locked loop has been out of lock.

6. The computer system of claim 1, wherein the lock detect indicator comprises:
reset circuitry that resets the lock detect indicator dependent on a reset input signal.

7. An integrated circuit, comprising:
circuitry that generates a first lock signal dependent on a first signal and a second signal used in a clock generator;
circuitry that generates a lock reset signal dependent on the first lock signal and a reset input signal;
circuitry that generates a second lock signal dependent on the lock reset signal; and
circuitry that outputs a lock status signal dependent on the second lock signal.

8. The integrated circuit of claim 7, wherein the clock generator is a phase locked loop.

9. The integrated circuit of claim 7, wherein the circuitry that outputs the lock status signal is dynamic.

10. The integrated circuit of claim 7, wherein the clock generator comprises:
a phase detector that inputs a system clock and a chip clock, wherein the phase detector generates the first signal and the second signal dependent on a phase relationship between the system clock and the chip clock.

11. The integrated circuit of claim 10, wherein the phase detector generates a pulse on the first signal when a phase of the system clock lags behind a corresponding phase of the chip clock, and wherein the phase detector generates a pulse on the second signal when a phase of the chip clock lags behind a corresponding phase of the system clock.

12. The integrated circuit of claim 10, further comprising:
circuitry that generates a clock generator pulse signal dependent on the system clock, chip clock, and the second lock signal.

13. The integrated circuit of claim 7, wherein the circuitry that generates the first lock signal comprises:
delay circuitry having a predetermined delay; and
circuitry that generates a pulse on the first lock signal when a pulse on the first signal or the second signal is greater than the predetermined delay.

14. The integrated circuit of claim 7, wherein the circuitry that generates the lock reset signal comprises:
circuitry that removes glitches on the first lock signal;
circuitry that amplifies a pulse on the first lock signal; and
circuitry that uses the pulse on the first lock signal to selectively reset the circuitry that generates the second lock signal.

15. The integrated circuit of claim 7, wherein the circuitry that generates the lock reset signal is dependent on a reset input signal.

16. The integrated circuit of claim 7, wherein the circuitry that generates the second lock signal comprises:
counter circuitry that counts to a particular value; and
circuitry that generates a pulse on the second lock signal when the counter circuitry reaches the particular value.

17. The integrated circuit of claim 7, further comprising:
circuitry that generates a past lock signal dependent on the second lock signal, wherein the past lock signal indicates whether the clock generator has been out of lock.

18. An integrated circuit, comprising:
generating means for generating a chip clock signal based on a system clock signal, wherein the generating means uses a first signal and a second signal to maintain a relationship between the chip clock and the system clock;
detecting means for using the first and second signals to determine whether the generating means is out of lock; and
indicating means for indicating whether the generating means is out of lock.

19. A method for detecting whether a phase locked loop is out of lock, comprising:
determining whether a pulse of a first signal or a second signal used in the phase locked loop is greater than a predetermined width;
generating a pulse on a first lock signal based on the determination; and
dynamically generating a pulse on a lock status signal dependent on the pulse on the first lock signal.

20. The method of claim 19, wherein the phase locked loop comprises a phase detector that inputs a system clock and a chip clock, wherein the phase detector generates the first signal and the second signal dependent on a phase relationship between the system clock and the chip clock.

21. The method of claim 20, wherein the phase detector generates a pulse on the first signal when a phase of the system clock lags behind a corresponding phase of the chip clock, and wherein the phase detector generates a pulse on the second signal when a phase of the chip clock lags behind a corresponding phase of the system clock.

22. The method of claim 20, further comprising:
generating a pulse signal of the phase locked loop dependent on the system clock and the pulse on the first lock signal.

23. The method of claim 19, wherein generating the first lock signal comprises:
using a predetermined delay; and
generating the pulse on the first lock signal when a pulse on the first signal or the second signal is greater than the predetermined delay.

24. The method of claim 19, further comprising generating a lock reset signal, wherein generating the lock reset signal comprises:
removing glitches on the first lock signal;
amplifying the pulse on the first lock signal; and
using the pulse on the first lock signal to selectively reset circuitry used for generating a second lock signal.

25. The method of claim 24, wherein generating the lock reset signal is dependent on a reset input signal.

26. The method of claim 24, wherein generating the second lock signal comprises:
counting to a particular value; and
generating a pulse on the second lock signal when circuitry used for counting to the particular value reaches the particular value.

27. The method of claim 24, further comprising:
generating a pulse on a past lock signal dependent on the second lock signal, wherein the past lock signal indicates whether the phase locked loop has been out of lock.
